(19) United States
(12) Patent Application Publication
(10) Pub. No.: US 2015/0333287 A1
(43) Pub. Date: Nov. 19, 2015

(54) ORGANIC ELECTROLUMINESCENT DEVICE, ILLUMINATION APPARATUS, AND ILLUMINATION SYSTEM

(71) Applicant: Kabushiki Kaisha Toshiba, Minato-ku (JP)

(72) Inventors: Tomoaki SAWABE, Sumida (JP); Tomio Ono, Yokohama (JP); Keiji SUGI, Fujisawa (JP); Shintaro Enomoto, Yokohama (JP)

(73) Assignee: Kabushiki Kaisha Toshiba, Minato-ku (JP)

(21) Appl. No.: 14/812,637

(22) Filed: Jul. 29, 2015

Related U.S. Application Data
(63) Continuation of application No. PCT/JP2013/077656, filed on Oct. 10, 2013.

(30) Foreign Application Priority Data
Feb. 4, 2013 (JP) 2013-019964

(51) Int. Cl. H01L 51/52; H01L 51/00; H05B 33/08

(52) U.S. Cl. CPC H01L 51/5215; H05B 33/0896; H01L 51/5221; H01L 51/5225; H01L 51/5209; H01L 51/5237; H01L 51/0096; H01L 2251/5361

(57) ABSTRACT

An organic electroluminescent device includes first and second substrates, first and second electrodes, an organic light emitting layer, and first and second terminal parts. The first substrate has an upper face including a device region and a periphery region surrounding the device region. The upper face is polygonal. The first electrode is provided on the device region. The organic light emitting layer is provided on the first electrode. The second electrode is provided on the organic light emitting layer. The second substrate is provided on the second electrode. The first terminal part is provided on the periphery region. The second terminal part is provided separated from the first terminal part on the periphery region. At least one of the first terminal part and the second terminal part extends along each of a plurality of sides of the upper face.

### CROSS-REFERENCE TO RELATED APPLICATIONS

This is a continuation application of International Application PCT/JP2013/077656, filed on Oct. 10, 2013; the entire contents of which are incorporated herein by reference.

### FIELD

Embodiments described herein relate generally to an organic electroluminescent device, an illumination apparatus, and an illumination system.

### BACKGROUND

There is an organic electroluminescent device that includes a first electrode, a second electrode, and an organic light emitting layer provided between the first electrode and the second electrode. There is an illumination apparatus using the organic electroluminescent device as a light source. There is an illumination system that includes a plurality of organic electroluminescent devices and a controller configured to control turning on and off of the plurality of organic electroluminescent devices. In the organic electroluminescent device, a light emitting area is made large by disposing side by side a plurality of devices and then connecting these in series or in parallel. In the organic electroluminescent device, desirably the wiring of the plurality of devices can be easily performed.

### BRIEF DESCRIPTION OF THE DRAWINGS

FIGS. 1A and 1B are schematic views showing an organic electroluminescent device according to a first embodiment;

FIGS. 2A and 2B are schematic plan views showing a part of an organic electroluminescent device according to the first embodiment;

FIGS. 3A to 3D are schematic plan views showing an organic electroluminescent device according to the first embodiment;

FIG. 4 is a schematic cross-sectional view showing a part of an organic electroluminescent device according to the first embodiment;

FIGS. 5A to 5C are schematic plan views showing a part of another organic electroluminescent device according to the first embodiment;

FIGS. 6A to 6C are schematic plan views showing other organic electroluminescent devices according to the first embodiment;

FIGS. 7A and 7B are schematic cross-sectional views showing other organic electroluminescent devices according to the first embodiment;

FIG. 8 is a schematic plan view showing another organic electroluminescent device according to the first embodiment;

FIGS. 9A to 9D are schematic plan views showing other organic electroluminescent devices according to the first embodiment;

FIGS. 10A and 10B are schematic plan views showing other organic electroluminescent devices according to the first embodiment;

FIG. 11 is a schematic plan view showing another organic electroluminescent device according to the first embodiment;

FIGS. 12A and 12B are schematic plan views of other organic electroluminescent devices according to the first embodiment;

FIG. 13 is a schematic view showing an illumination apparatus according to a second embodiment; and

FIGS. 14A to 14C are schematic views showing illumination systems according to a third embodiment.

### DETAILED DESCRIPTION

According to one embodiment, an organic electroluminescent device includes a first substrate, a first electrode, an organic light emitting layer, a second electrode, a second substrate, a first terminal part, and a second terminal part. The first substrate has an upper face including a device region and a periphery region surrounding the device region. The upper face is polygonal. The first substrate is light transmissive. The first electrode is provided on the device region. The organic light emitting layer is provided on the first electrode. The second electrode is provided on the organic light emitting layer. The second substrate is provided on the second electrode and covers the organic light emitting layer and the second electrode. The first terminal part is provided on the periphery region and is electrically connected to the first electrode. The second terminal part is provided separated from the first terminal part on the periphery region and is electrically connected to the second electrode. The first terminal part includes at least a portion extending along one side of the upper face and a portion extending along an adjacent side of the one side. The second terminal part includes at least a portion extending along other one side different from the one side and a portion extending along a side adjacent to the other one side. At least one of the first terminal part and the second terminal part extends along each of a plurality of sides of the upper face.

According to another embodiment, an illumination apparatus includes an organic electroluminescent device and a power source. The organic electroluminescent device includes a first substrate, a first electrode, an organic light emitting layer, a second electrode, a second substrate, a first terminal part, and a second terminal part. The first substrate has an upper face including a device region and a periphery region surrounding the device region. The upper face is polygonal. The first substrate is light transmissive. The first electrode is provided on the device region. The organic light emitting layer is provided on the first electrode. The second electrode is provided on the organic light emitting layer. The second substrate is provided on the second electrode and covers the organic light emitting layer and the second electrode. The first terminal part is provided on the periphery region and is electrically connected to the first electrode. The second terminal part is provided separated from the first terminal part on the periphery region and is electrically connected to the second electrode. The power source is electrically connected to the first electrode and the second electrode and supplies a current to the organic light emitting layer via the first electrode and the second electrode. The first terminal part includes at least a portion extending along one side of the upper face and a portion extending along an adjacent side of the one side. The second terminal part includes at least a portion extending along other one side different from the one side and a portion extending along a side adjacent to the other one side. At least one of the first terminal part and the second terminal part extends along each of a plurality of sides of the upper face.

According to another embodiment, an illumination system includes a plurality of organic electroluminescent devices and a controller. Each of the organic electroluminescent devices includes a first substrate, a first electrode, an organic light emitting layer, a second electrode, a second substrate, a first terminal, and a second terminal. The first substrate has an upper face including a device region and a periphery region surrounding the device region. The upper face is polygonal. The first substrate is light transmissive. The first electrode is provided on the device region. The organic light emitting layer is provided on the first electrode. The second electrode is provided on the organic light emitting layer. The second substrate is provided on the second electrode and covers the organic light emitting layer and the second electrode. The first terminal part is provided on the periphery region and is electrically connected to the first electrode. The second terminal part is provided separated from the first terminal part on the periphery region and is electrically connected to the second electrode. The controller is electrically connected to each of the organic electroluminescent devices and controls turning on and off of each of the organic electroluminescent devices. The first terminal part includes at least a portion extending along one side of the upper face and a portion extending along an adjacent side of the one side. The second terminal part includes at least a portion extending along other one side different from the one side and a portion extending along a side adjacent to the other one side. At least one of the first terminal part and the second terminal part extends along each of a plurality of sides of the upper face.

Various embodiments will be described hereinafter with reference to the accompanying drawings.

The drawings are schematic or conceptual; and the relationships between the thicknesses and the widths of portions, the proportions of sizes between portions, etc., are not necessarily the same as the actual values thereof. Also, the dimensions and/or the proportions may be illustrated differently between the drawings, even for identical portions.

In the drawings and the specification of the application, components similar to those described in regard to a drawing thereinabove are marked with like reference numerals, and a detailed description is omitted as appropriate.

### First Embodiment

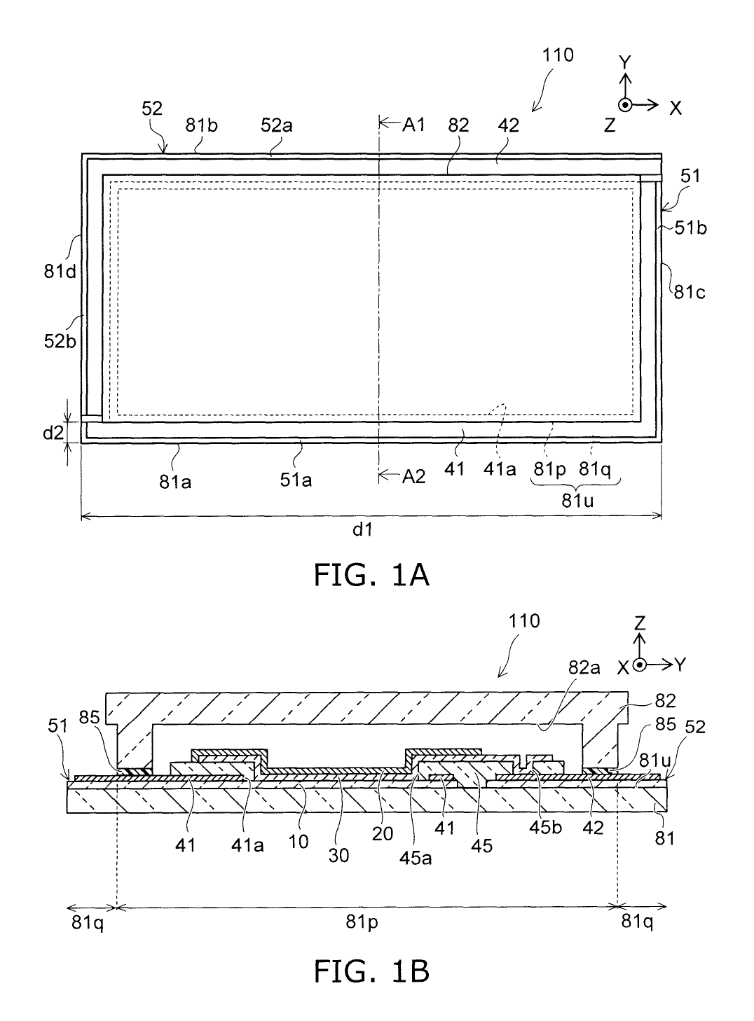

FIGS. 1A and 1B are schematic views showing an organic electroluminescent device according to a first embodiment.

FIG. 1A is a schematic plan view, and FIG. 1B is a schematic cross-sectional view. FIG. 1B shows a cross-section along an A1-A2 line in FIG. 1A.

As shown in FIGS. 1A and 1B, an organic electroluminescent device 110 includes a first electrode 10, a second electrode 20, an organic light emitting layer 30, a first terminal part 51, a second terminal part 52, a first substrate 81, and a second substrate 82. In the example, the organic electroluminescent device 110 further includes a first wiring layer 41 and a second wiring layer 42. The first wiring layer 41 and the second wiring layer 42 are provided as appropriate and can be omitted.

The first substrate 81 has light permeability. The first substrate 81 is, for example, transparent. The first substrate 81 has a polygonal upper face 81u. The upper face 81u includes a device region 81p, and a periphery region 81q surrounding the device region 81p. In the example, the upper face 81u is quadrangular. The upper face 81u has a first side 81a and a second side 81b facing the first side 81a, a third side 81c connecting one end of the first side 81a with one end of the second side 81b, and a fourth side 81d connecting the other end of the first side 81a with the other end of the second side 81b.

The upper face 81u is, more specifically, rectangular. That is, in the example, the first side 81a is substantially parallel to the second side 81b. The third side 81a is substantially parallel to the fourth side 81d. The first side 81a and the second side 81b are substantially perpendicular to the third side 81c and the fourth side 81d.

The upper face 81u is not limited to be in a rectangular shape, but may be in a trapezoidal shape or a parallelogramic shape. The upper face 81u is not limited to be quadrangular, but may be arbitrarily polygonal such as triangular or hexagonal. Note that, in the specification of the application, a “polygonal shape” is assumed to include, for example, a shape in which the apex portion is rounded, a shape in which the apex portion is chamfered, or the like. A “polygonal shape” may be generally polygonal when the upper face 81u is projected onto a plane parallel to the face (when viewed from above). Furthermore, in the specification of the application, a “side” is assumed to include, in addition to a linear one, those slightly curved, those having slight irregularity, or the like. In the specification of the application, the “side” means, for example, that a ratio of the length of the upper face 81u in the direction in which the outer edge extends and the displacement of the outer edge in the direction orthogonal to the extending direction is less than 5%.

Here, the direction perpendicular to the upper face 81u is defined as a Z-axis direction. One direction parallel to the upper face 81u is defined as an X-axis direction. The direction perpendicular to the X-axis direction and the Z-axis direction is defined as a Y-axis direction. The X-axis direction and the Y-axis direction are directions perpendicular to the Z-axis direction. The Z-axis direction corresponds to the thickness direction of the first substrate 81.

In the example, the first side 81a and the second side 81b extend in the X-axis direction, and the third side 81c and the fourth side 81d extend in the Y-axis direction. For example, the displacement of the first side 81a in the Y-axis direction is less than 5% relative to the length of the first side 81a in the X-axis direction.

The first electrode 10 is provided on the device region 81p in the upper face 81u of the first substrate 81. The first electrode 10 has, for example, light permeability. The first electrode 10 is, for example, a transparent electrode.

The organic light emitting layer 30 is provided on the first electrode 10. The organic light emitting layer 30 has light permeability. The organic light emitting layer 30 is, for example, transparent.

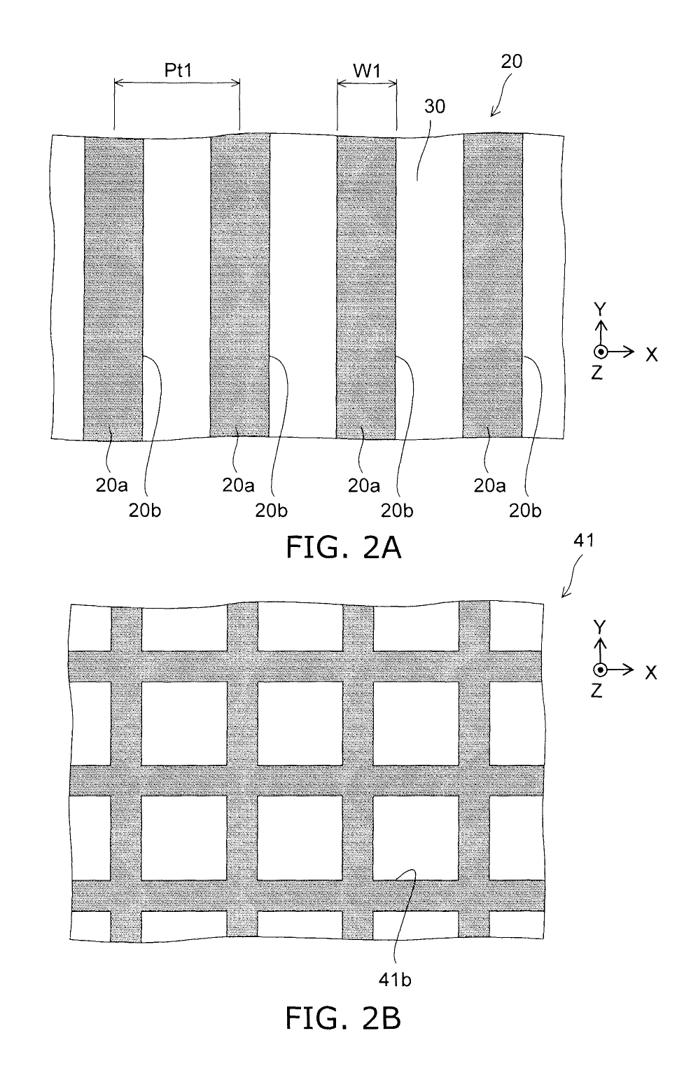

FIGS. 2A and 2B are schematic plan views showing a part of an organic electroluminescent device according to the first embodiment.

FIG. 2A is a schematic plan view expanding and showing merely the second electrode 20.

The second electrode 20 is provided on the organic light emitting layer 30. The second electrode 20 has a conductive part 20a and an aperture part 20b. The second electrode 20 has, for example, a plurality of conductive parts 20a and a plurality of aperture parts 20b. Each of the plurality of conductive parts 20a extends in the Y-axis direction and is arranged side by side in the X-axis direction.

Each of the plurality of aperture parts 20b is disposed between each of the plurality of conductive parts 20a. In the example, each of the plurality of aperture parts 20b is in a trench shape extending in the Y-axis direction. Each of the plurality of aperture parts 20b extends in the Y-axis direction and is arranged side by side in the X-axis direction. Each of the plurality of aperture parts 20b allows, for example, a part of the organic light emitting layer 30 to be exposed. In the example, the second electrode 20 is in a stripe-like shape. That is, the second electrode 20 does not overlap with a part of the first electrode 10 when being projected onto a plane parallel to the upper face 81u. For example, it allows a part of the upper face 81u of the first substrate 81 to be exposed. In the example, the second electrode 20 is in a stripe-like shape. That is, the second electrode 20 does not overlap with a part of the upper face 81u when being projected onto a plane parallel to the upper face 81u.

The second electrode 20 (the conductive part 20a) has, for example, light reflectivity. The light reflectance of the second electrode 20 is higher than the light reflectance of the first electrode 10. In the specification of the application, the state of having light reflectance higher than the light reflectance of the first electrode 10 is referred to as being light reflective.

In the example, an insulating layer 45 is furthermore provided between the first electrode 10 and the organic light emitting layer 30. In the insulating layer 45, an aperture part 45a is provided. The aperture part 45a allows a part of the first electrode 10 to be exposed. The aperture part 45a may be provided, for example, in plural number. The insulating layer 45 extends between the first electrode 10 and the second electrode 20 in a portion, for example, where, when being projected onto the X-Y plane, the first electrode 10 and the organic light emitting layer 30 do not overlap with each other and the first electrode 10 and the second electrode 20 overlap with each other. Consequently, the insulating layer 45 suppresses, for example, short circuit between the first electrode 10 and the second electrode 20. Further, the insulating layer 45 protects, for example, a portion to be the light emitting region of the organic light emitting layer 30 in forming the second electrode 20, etc. Furthermore, the insulating layer 45 is provided, for example, so as to cover each edge part (outer border) of the first electrode 10, the first wiring layer 41 and the second wiring layer 42. Consequently, the insulating layer 45 suppresses, for example, the electric field concentration at each edge part of the first electrode 10, the first wiring layer 41 and the second wiring layer 42. For example, it suppresses short circuit between the first electrode 10 and the second electrode 20. For example, it suppresses short circuit between the first electrode 10 and the second wiring layer 42. For example, it suppresses short circuit between the second electrode 20 and the second wiring layer 42.

The second substrate 82 has light permeability. The second substrate 82 is, for example, transparent. The second substrate 82 is provided on the second electrode 20. The second substrate 82 covers the organic light emitting layer 30 and the second electrode 20. The second substrate 82 overlaps with a device region 81p in the upper face 81u of the first substrate 81 when being projected onto a plane parallel to the X-Y plane. In other words, the device region 81p is a region of the upper face 81u, which overlaps with the second substrate 82 when being projected onto the X-Y plane.

The second substrate 82 has a concave part 82a. The depth of the concave part 82a (the length in the Z-axis direction) is longer than the length from the upper face 81u to the upper face of the second electrode 20 in the Z-axis direction.

The second substrate 82 houses the second electrode 20 and the organic light emitting layer 30 in the space inside the concave part 82a.

Between the first substrate 81 and the second substrate 82, a seal part 85 is provided. The seal part 85 is, for example, provided annularly along peripheries of the first substrate 81 and the second substrate 82, and unites the first substrate 81 with the second substrate 82. Consequently, the second electrode 20, the organic light emitting layer 30 etc. are sealed with the first substrate 81 and the second substrate 82. Consequently, for example, the organic light emitting layer 30 can be protected from moisture etc. The seal part 85 has, for example, light permeability. The seal part 85 is, for example, transparent.

The second substrate 82 may be in a plate-like shape. When the plate-like second substrate 82 is used, the first substrate 81 and the second substrate 82 are united with the seal part 85. The seal part 85 is provided so as to surround the device region 81p. The thickness of the seal part 85 in the Z-axis direction is larger than the distance between the face of the first electrode 10 opposite to the first substrate 81 and the face of the second electrode 20 opposite to the second substrate 82.

In the space inside the concave part 82a, for example, inert gas or the like is filled. In the inside of the concave part 82a, a desiccant or the like may be provided. The space inside the concave part 82a may be, for example, an air layer. For example, the vacuum degree of the space inside the concave part 82a may be made high. In the space inside the concave part 82a, for example, a liquid acrylic-based resin or epoxy-based resin may be filled. A material to be filled may be one capable of being filled in the space between the first substrate 81 and the second substrate 82, and is not limited to these materials. Further, to the acrylic-based resin or epoxy-based resin, as a desiccant, calcium oxide, barium oxide or the like may be added. It is sufficient that the desiccant has a function of adsorbing moisture and oxygen and is not limited to these materials.

In the case where the second substrate 82 is in a plate-like shape, in the same way, in the space in the inside formed by sticking the first substrate 81 and the second substrate 82, for example, an inert gas or the like is filled. In the inside formed by sticking the first substrate 81 and the second substrate 82, a desiccant or the like may be provided. The space in the inside formed by sticking the first substrate 81 and the second substrate 82 may be, for example, an air layer. For example, the vacuum degree of the space in the inside formed by sticking the first substrate 81 and the second substrate 82 may be made high. In the space in the inside formed by sticking the first substrate 81 and the second substrate 82, for example, a liquid acrylic-based resin or epoxy-based resin may be filled. The material to be filled may be one that can be filled in the space between the first substrate 81 and the second substrate 82 and may not be limited to these materials. Further, to the acrylic-based resin and epoxy-based resin, as a desiccant, calcium oxide or barium oxide may be added. It is sufficient that the desiccant has a function of adsorbing moisture and oxygen, and is not limited to these materials.

The first terminal part 51 is provided on the periphery region 81q. The first terminal part 51 is electrically connected to the first electrode 10. For the first terminal part 51, a conductive material is used. The first terminal part 51 includes at least a portion extending along one side of the upper face 81u, and a portion extending along a side adjacent to one side. In the example, first terminal part 51 includes a portion 51a extending along the first side 81a of the upper face 81u and a portion 51b extending along the third side 81c adjacent to the first side 81a. Here, “extending along the side” means, for example, that, in the first terminal part 51 and the second terminal part 52, a length extending in the direction parallel to the side is not less than a length extending in the direction perpendicular to the side. For example, a length dl of one portion 51a of the first terminal part 51 extending in the direction parallel to the first side 81a is not less than a length d2 extending in the direction perpendicular to the first side 81a of the portion 51a. In the specification of the application, “electrically connected to” includes a case where another conductive member or the like intervenes in addition to a case of direct contact.

The second terminal part 52 is provided separated from the first terminal part 51 over the periphery region 81q. The second terminal part 52 is electrically connected to the second electrode 20. The second terminal part 52 is electrically insulated from the first terminal part 51. For the second terminal part 52, a conductive material is used. The second terminal part 52 includes at least a portion extending along a side different from one side of the first terminal part 51 of the upper face 81u, and a portion extending along a side adjacent to one side. In the extending example, the second terminal part 52 includes a portion 52a along the second side 81b of the upper face 81u and a portion 52b extending along the fourth side 81d adjacent to the second side 81b.

As described above, the first terminal part 51 and the second terminal part 52 are disposed so that at least one of the first terminal part 51 and the second terminal part 52 extends along each of the plurality of sides of the upper face 81u. In the example, in each of the four sides 81a to 81d of the upper face 81u, the first terminal part 51 extends along the first side 81a and the third side 81c, and the second terminal part 52 extends along the second side 81b and the fourth side 81d.

In the example, the first terminal part 51 and the second terminal part 52 have light permeability. The first terminal part 51 and the second terminal part 52 are, for example, transparent. In the example, the first terminal part 51 extends on the device region 81p in the upper face 81u of the first substrate 81. The first terminal part 51 contains substantially the same material as that of the first electrode 10, and is continuous with the first electrode 10. That is, in the example, the first terminal part 51 is inseparable from the first electrode 10. In the example, by forming the first terminal part 51 inseparable from the first electrode 10, the first terminal part 51 is electrically connected to the first electrode 10. The first terminal part 51 may not be continuous with the first electrode 10. Electric connection between the first terminal part 51 and the first electrode 10 may be achieved via another conductive member.

In the example, the second terminal part 52 contains substantially the same material as that of the first electrode 10. The second terminal part 52 is formed, for example, from the same conductive film as that of the first electrode 10 and the first terminal part 51. For example, a light transmissive conductive film is formed over the first substrate 81, and the conductive film is patterned. Consequently, from the conductive film, the first electrode 10, the first terminal part 51 and the second terminal part 52 are formed.

In the example, the second terminal part 52 extends on the device region 81p in the upper face 81u of the first substrate 81. Above the device region 81p, the insulating layer 45 extends on the second terminal part 52. For the portion of the insulating layer 45 overlapping with the second terminal part 52, an aperture part 45b is provided. The aperture part 45b allows a part of the second terminal part 52 to be exposed. A part of the second electrode 20 enters the inside of the aperture part 45b, and extends on the part of the second terminal part 52 allowed to be exposed by the aperture part 45b. The second electrode 20 comes into contact with a part of the second terminal part 52, for example, in the portion of the aperture part 45b. Consequently, the second electrode 20 and the second terminal part 52 are electrically connected to each other.

As described above, the shape of the first terminal part 51 and the second terminal part 52 projected onto the X-Y plane are not necessarily the same as the shape of the portion positioned outside the second substrate 82. It is sufficient that the first terminal part 51 and the second terminal part 52 have a plurality of portions extending along the side of the upper face 81u in a portion positioned at least outside the second substrate 82. For example, in the first terminal part 51 and the second terminal part 52, the shape of the portion not overlapping, when being projected onto the X-Y plane, with the second substrate 82 may have a plurality of portions extending along the side of the upper face 81u.

The first wiring layer 41 is provided, for example, between the first electrode 10 and the organic light emitting layer 30. In the example, the first wiring layer 41 extends along the periphery of the first electrode 10. The first wiring layer 41 is, for example, annular. The first wiring layer 41 has an aperture part 41a. The aperture part 41a allows a part of the first electrode 10 to be exposed. That is, the first wiring layer 41 does not overlap with a part of the first electrode 10 when being projected onto the X-Y plane.

The first wiring layer 41 contains a conductive material. The first wiring layer 41 is electrically connected to the first electrode 10. The first wiring layer 41 makes contact with, for example, the first electrode 10. The electroconductivity of the first wiring layer 41 is higher than the electroconductivity of the first electrode 10. The first wiring layer 41 has light reflectivity. The light reflectance of the first wiring layer 41 is higher than the light reflectance of the first electrode 10. The first wiring layer 41 is, for example, a metal wiring. The first wiring layer 41 functions as, for example, an auxiliary electrode transmitting a current flowing to the first electrode 10. Consequently, for example, a current quantity flowing in a direction parallel to the X-Y plane of the first electrode 10 can be made uniform. For example, the emission luminance in the plane can be made more uniform.

In the example, the first wiring layer 41 extends on the first terminal part 51. The first wiring layer 41 is electrically connected to the first terminal part 51. The first wiring layer 41 makes contact with, for example, the first electrode 10. The electroconductivity of the first wiring layer 41 is higher than the electroconductivity of the first terminal part 51. Consequently, for example, the transmission of a current flowing to the first terminal part 51 can be assisted. For example, the electric resistance value in the portion of the first terminal part 51 can be reduced.

The second wiring layer 42 is provided on, for example, the second terminal part 52. The second wiring layer 42 contains a conductive material. The second wiring layer 42 is electrically connected to the second terminal part 52. The second wiring layer 42 makes contact with, for example, the second terminal part 52. The second wiring layer 42 has light reflectivity. The light reflectance of the second wiring layer 42 is higher than the light reflectance of the first electrode 10. The second wiring layer 42 is, for example, a metal wiring. The electroconductivity of the second wiring layer 42 is higher than the electroconductivity of the second terminal part 52. The second wiring layer 42 functions as, for example, an auxiliary wiring that assists the transmission of a current flowing to the second terminal part 52. For example, an electric resistance value in the portion of the second terminal part 52 is reduced.

In the example, the second wiring layer 42 extends on the device region 81p. The second wiring layer 42 extends between, for example, the second electrode 20 and the second terminal part 52. Consequently, it is possible to make a current flow easily between the second electrode 20 and the second terminal part 52.

FIG. 2B is a schematic plan view expanding and showing merely the first wiring layer 41.

As shown in FIG. 2B, the first wiring layer 41 includes a plurality of aperture parts 41b. Each of the aperture parts 41b is disposed side by side in a two-dimensional matrix shape. That is, in the example, the first wiring layer 41 is in a mesh shape. Consequently, light permeability can be achieved in a portion of the first terminal part 51.

The first wiring layer 41 may be in a stripe-like shape. When the first wiring layer 41 is made in a stripe-like shape, the stripe can be formed parallel to one side of the upper face 81u. When being made in a stripe-like shape parallel to one side of the upper face 81u, potential fall of the first terminal part 51 can be reduced. When the layer is made in a mesh-like shape, positioning of the coupling member with the first terminal part 51 becomes easy, for example, in being connected with another organic electroluminescent device 110 by a coupling member to be described later. Note that the first wiring layer 41 may not include the aperture part 41b. That is, the portion of the first terminal part 51 may be light reflective.

The second wiring layer 42 is in a mesh shape, in the same way as the first wiring layer 41. Consequently, in the portion of the second terminal part 52, light permeability can be achieved. The second wiring layer 42 may be in a stripe-like shape. When the second wiring layer 42 is made in a stripe-like shape, the stripe can be formed parallel to one side of the upper face 81u. When being made in a stripe-like shape parallel to one side of the upper face 81u, potential fall of the second terminal part 52 can be reduced. When the layer is made in a mesh-like shape, for example, in being connected with another organic electroluminescent device 110 with a coupling member to be described later, positioning of the coupling member with the second terminal part 52 becomes easy. The second wiring layer 42 may be formed as a continuous layer not including an aperture part. That is, the portion of the second terminal part 52 may be light reflective.

The organic light emitting layer 30 extends on a part of the first electrode 10 exposed by the aperture part 45a. The organic light emitting layer 30 is, for example, in connection with a part of the first electrode 10 exposed by the aperture part 45a. Consequently, the organic light emitting layer 30 is electrically connected to the first electrode 10.

The organic light emitting layer 30 is electrically connected to the second electrode 20. The organic light emitting layer 30 makes contact with, for example, each of the plurality of conductive parts 20a. Consequently, the organic light emitting layer 30 is electrically connected to the second electrode 20.

A voltage is applied, or a current is supplied to the organic light emitting layer 30 via the first electrode 10 and the second electrode 20. Consequently, the organic light emitting layer 30 emits light. The organic light emitting layer 30 causes, for example, an electron injected from a cathode and a hole injected from an anode to recombine by the application of a voltage or the supply of a current to thereby generate an exciton. The organic light emitting layer 30 emits light, for example, while utilizing the ejection of light when the exciton is radiatively deactivated.

In the organic electroluminescent device 110, the portion of the organic light emitting layer 30 between the first electrode 10 and the conductive part 20a serves as an emission region. In the example, the organic light emitting layer 30 has a plurality of emission regions between the first electrode 10 and each of the plurality of conductive parts 20a. The emission light emitted from the emission regions exits to the outside of the organic electroluminescent device 110 via the first electrode 10 and the first substrate 81. A part of the emission light is reflected by the second electrode 20 and exits to the outside via the organic light emitting layer 30, the first electrode 10 and the first substrate 81. That is, the organic electroluminescent device 110 is of a one-side light emission type.

In the organic electroluminescent device 110, outside light entering the device from the outside passes through the first electrode 10 and the organic light emitting layer 30 in portions positioned between each of the plurality of conductive parts 20a. In this way, the organic electroluminescent device 110 causes the emission light to exit to the outside and allows the outside light entering the organic electroluminescent device 110 from the outside to pass through. As described above, the organic electroluminescent device 110 has light permeability. Consequently, in the organic electroluminescent device 110, an image in a background can be visually recognized via the organic electroluminescent device 110. That is, the organic electroluminescent device 110 is a thin film-like or plate-like light source capable of being seen through.

In this way, according to the organic electroluminescent device 110, a light transmissive organic electroluminescent device can be provided. When the organic electroluminescent device 110 is applied to illumination apparatuses, various new applications become possible by a function of allowing a background image to be seen through in addition to an illumination function.

Further, in the organic electroluminescent device 110, the first terminal part 51 and the second terminal part 52 also have light permeability. In the organic electroluminescent device 110, the device is light transmissive except for the plurality of thin wire-like conductive parts 20a, the thin wire-like first wiring layer 41 and second wiring layer 42. That is, in the organic electroluminescent device 110, approximately the whole is light transmissive. Approximately the whole of the organic electroluminescent device 110 is transparent. Consequently, for example, in the organic electroluminescent device 110, visibility of a transmission image can be enhanced.

In organic electroluminescent devices, it is performed to make a light emitting area large by disposing side by side a plurality of devices. As a method for feeding power to each of the plurality of organic electroluminescent devices, for example, there is a method of connecting a feeder wire for an anode and a feeder wire for a cathode to each of the plurality of organic electroluminescent devices. However, in such a method for feeding power, as many feeder wires as the number of devices become required and wiring becomes complicated. Further, there is a method in which a plurality of devices are disposed side by side on an exclusive wiring substrate and power is fed to the plurality of devices via the wiring substrate. However, in the method, although the number of feeder wires can be reduced, a wiring substrate becomes required and the configuration becomes complicated. For example, the number of parts increases to bring about the increase in cost.

In contrast, in the organic electroluminescent device 110 according to the embodiment, the first terminal part 51 and the second terminal part 52 have a plurality of portions extending along the side of the upper face 81u. Further, at least one of the first terminal part 51 and the second terminal part 52 is configured to extend along each of the plurality of sides of the upper face 81u. Consequently, for example, when the plurality of organic electroluminescent devices 110 are disposed side by side, in adjacent two organic electroluminescent devices 110, the first terminal part 51 of one organic electroluminescent device 110 faces the first terminal part 51 or the second terminal part 52 of another organic electroluminescent device 110. For example, first terminal parts 51 facing each other, second terminal parts 52 facing each other, or the first terminal part 51 and the second terminal part 52 facing each other are connected with a conductive coupling member. Consequently, two organic electroluminescent devices 110 can be easily electrically connected to each other.

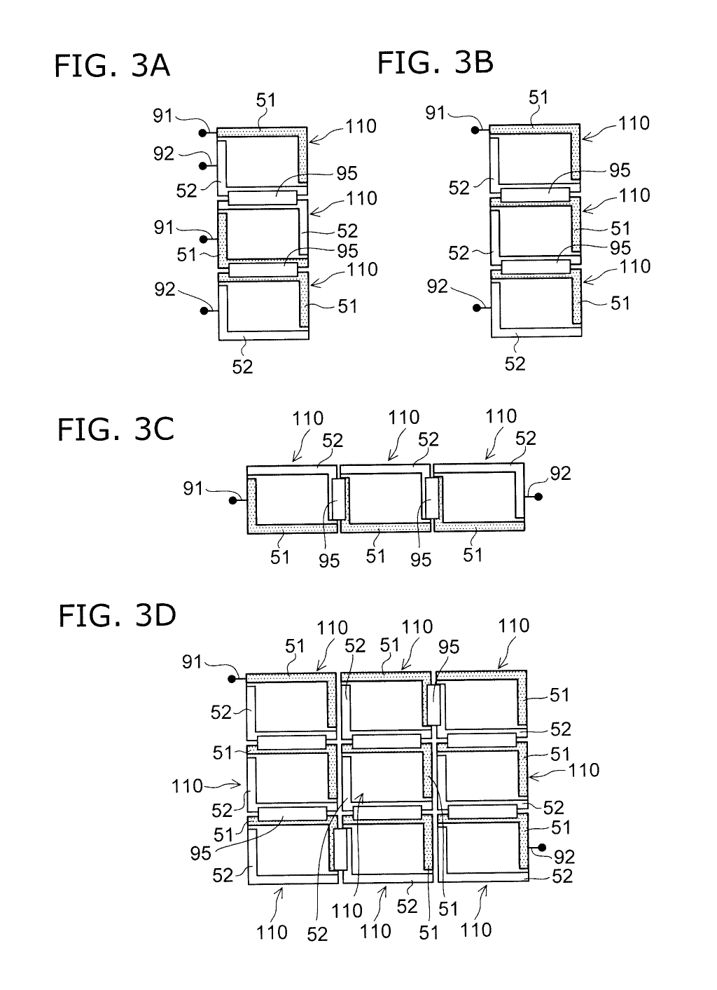

FIGS. 3A to 3D are schematic plan views showing an organic electroluminescent device according to the first embodiment.

FIG. 3A shows a state where three organic electroluminescent devices 110 are arranged side by side in the Y-axis direction and each of these is connected in parallel.

As shown in FIG. 3A, for example, a coupling member 95 is used for electric connection between adjacent two organic electroluminescent devices 110. The coupling member 95 is, for example, a film-like member having electroconductivity, a conductive member soldered with a lead wire, and a bonded conductive wire such as a metal wire. The coupling member 95 is stuck to the first terminal part 51 or the second terminal part 52. Consequently, adjacent two organic electroluminescent devices 110 can be electrically connected.

Furthermore, the coupling member 95 has, for example, light permeability. The coupling member 95 is, for example, transparent. Consequently, the coupling member 95 can be made indistinctive in connecting electrically two organic electroluminescent devices 110 having light permeability. For example, visibility of a transmission image can be enhanced.

As shown in FIG. 3A, the second terminal part 52 of a first organic electroluminescent device 110 is connected with the second terminal part 52 of a second organic electroluminescent device 110 with the coupling member 95. The first terminal part 51 of the second organic electroluminescent device 110 is connected with the first terminal part 51 of a third organic electroluminescent device 110 by using the coupling member 95. The first terminal part 51 of the first organic electroluminescent device 110 and the first terminal part 51 of the second organic electroluminescent device 110 are connected with a first feeder wire 91 of one of the anode and the cathode. The second terminal part 52 of the first organic electroluminescent device 110 and the second terminal part 52 of the third organic electroluminescent device 110 are connected with a second feeder wire 92 of the other of the anode and the cathode. Consequently, three organic electroluminescent devices 110 can be connected in parallel.

FIG. 3B shows a state where three organic electroluminescent devices 110 are arranged side by side in the Y-axis direction and each of these is connected in series.

As shown in FIG. 3B, the second terminal part 52 of a first organic electroluminescent device 110 is connected with the first terminal part 51 of a second organic electroluminescent device 110 by using the coupling member 95. The second terminal part 52 of the second organic electroluminescent device 110 is connected with the first terminal part 51 of a third organic electroluminescent device 110 by using the coupling member 95. The first terminal part 51 of the first organic electroluminescent device 110 is connected with the first feeder wire 91. The second terminal part 52 of the third organic electroluminescent device 110 is connected with the second feeder wire 92. Consequently, three organic electroluminescent devices 110 can be connected in series.

FIG. 3C shows a state where three organic electroluminescent devices 110 are arranged side by side in the X-axis direction and each of these is connected in series.

As shown in FIG. 3C, in the organic electroluminescent device 110, the plurality of organic electroluminescent devices 110 can also be arranged side by side in the X-axis direction and connected in series.

FIG. 3D shows a state where nine organic electroluminescent devices 110 are arrayed in a two-dimensional matrix shape in the X-axis direction and the Y-axis direction, and each of these is connected in series.

As shown in FIG. 3D, in the organic electroluminescent device 110, the plurality of organic electroluminescent devices 110 can also be arrayed in a two-dimensional matrix shape and be connected in series.

In this way, in the organic electroluminescent device 110 according to the embodiment, adjacent two organic electroluminescent devices 110 can be easily connected electrically with the coupling member 95. Then, in the organic electroluminescent device 110, the number of first feeder wires 91 and second feeder wires 92 can be reduced. For example, when each of three organic electroluminescent devices 110 is connected with the first feeder wire 91 and the second feeder wire 92, three first feeder wires 91 and three second feeder wires 92 become required. In contrast, for example, in the case of the connection in series with the coupling member 95, merely one first feeder wire 91 and one second feeder wire 92 may be connected.

In the organic electroluminescent device 110 according to the embodiment, the width of the coupling member 95 can be made long. For example, in the coupling member 95, the length extending in the direction parallel to the side can be set to be not less than the length extending in the direction perpendicular to the side. The width of the coupling member 95 means the length in the direction parallel to the sides of respective devices in the portion connecting two organic electroluminescent devices 110. For example, in FIG. 3A, the width of the coupling member 95 is the length in the direction parallel to the first side 81a and the second side 81b of the coupling member 95 (the length in the X-axis direction). Consequently, for example, the width of the coupling member 95 can be made wide to thereby suppress the resistance value. Accordingly, for example, useless power consumption when the plurality of organic electroluminescent devices 110 are electrically connected can be suppressed. Furthermore, a connection area of the coupling member 95 can be made large, or connection places can be increased, and, as the result, the reliability of connection parts can be enhanced.

For example, when trying to connect electrically adjacent two organic electroluminescent devices with a coupling member 95 having a width of length d2, since the width of the coupling member 95 is narrow, useless power consumption is generated. In contrast, in the organic electroluminescent device 110 according to the embodiment, for example, adjacent two organic electroluminescent devices can be connected electrically with a coupling member having a width of length d1. Consequently, the width of the coupling member 95 can be made wide, and the resistance value can be suppressed and useless power consumption can be suppressed. For example, the electroconductivity of a transparent conductive material such as ITO is lower than the electroconductivity of a metal material etc. Therefore, in a configuration in which the width of the coupling member 95 can not be made wide, when the first terminal part 51, the second terminal part 52, the coupling member 95 etc. are made light transmissive, the influence caused by the power consumption of the coupling member 95 becomes large. In the organic electroluminescent device 110 according to the embodiment, even when the first terminal part 51, the second terminal part 52, the coupling member 95 etc. are made light transmissive, the width of the coupling member 95 can be made wide and the power consumption by the coupling member 95 can be suppressed suitably. For a light transmissive coupling member 95, an auxiliary wiring in a thin line shape or in a lattice-like shape may be provided. The electroconductivity of the auxiliary wiring is made higher than the electroconductivity of the light transmissive coupling member 95. Consequently, for example, the coupling member 95 can suppress resistance while having light permeability, and power loss in the coupling member 95 can be reduced.

As described above, in the organic electroluminescent device 110 according to the embodiment, each of a plurality of organic electroluminescent devices 110 can be easily wired in series or in parallel. The number of feeder wires for feeding power from the outside can be made small. Separate preparation of a wiring substrate or the like is unrequired, and the increase in the number of parts can be suppressed. Useless power consumption caused by the coupling member 95 can be suppressed.

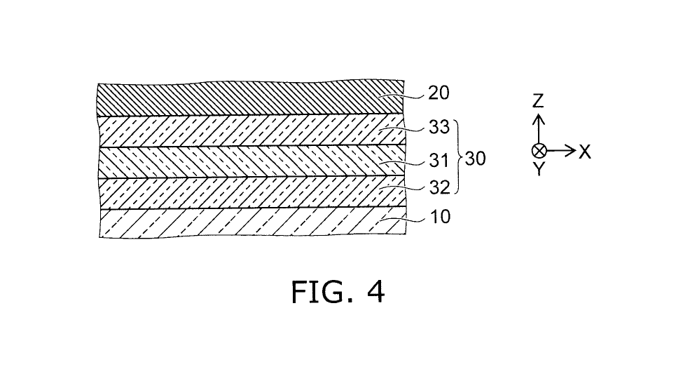

FIG. 4 is a schematic cross-sectional view showing a part of an organic electroluminescent device according to the first embodiment.

As shown in FIG. 4, the organic light emitting layer 30 includes a first layer 31. The organic light emitting layer 30 may further include, as appropriate, at least any one of a second layer 32 and a third layer 33. The first layer 31 emits light including the wavelength of visible light. The second layer 32 is provided between the first layer 31 and the first electrode 10. The third layer 33 is provided between the first layer 31 and the second electrode 20.

For example, a material such as Alq₃ (tris(8-hydroxyquinolinolato)aluminum), F8BT (poly(9,9-dioctylfluorene-co-benzothiadiazole) or PPV (poly(p-phenylenevinylene)) can be used for the first layer 31. A mixing material of a host material and a dopant added to the host material can be used for the first layer 31. As the host material, for example, CBP (4,4′-N,N′-bis(dicarbazolyl-biphenyl)), BCP (2,9-dimethyl-4,7-diphenyl-1,10-phenanthroline), TPD (4,4′-bis-N-3-methylphenyl-N-phenylaminobiphenyl), PVK (polyvinyl carbazole), PPT (poly(3-phenylthiophene)) or the like can be used as the host material. For example, Flrpic (iridium (III) bis(4,6-di-fluorophenyl)-pyridinate-N,C2′-picolinate), Ir(ppy)₃ (tris (2-phenylpyridine)iridium), FIr6 (bis(2,4-difluorophenylpyridinate)-tetrakis(1-pyrazolyl)borate-iridium(III)) or the like can be used as a dopant material. The first layer is not limited to layers formed of these materials.

The second layer 32 functions as, for example, a hole injection layer. The hole injection layer includes at least any of, for example, PEDPOT: PPS (poly(3,4-ethylenedioxythiophene)-poly(styrenesulfonate)), CuPc (copper phthalocyanine), MoO₃ (molybdenumtrioxide), and the like. The second layer 32 functions as, for example, a hole transport layer. The hole transport layer includes at least any of, for example, a-NPD (4,4′-bis[N-(1-naphthyl)-N-phenylamino]biphenyl), TAPC (1,1-bis[4-[N,N-di(p-tolyl)amino]phenyl]cyclohexane), m-MTDATA (4,4′,4″-tris[phenyl(m-tolyl)amino]triphenylamine), TPD (bis(3-methylphenyl)-N,N′-diphenylbenzidine), TCTA (4,4′,4″-tri(N-carbazolyl)triphenylamine), and the like. The second layer 32 may have a stacked structure, for example, of a layer functioning as a hole injection layer and a layer functioning as a hole transport layer. The second layer 32 may include a layer other than the layer functioning as a hole injection layer and a layer functioning as a hole transport layer. The second layer 32 is not limited to layers formed of these materials.

The third layer 33 may include a layer functioning as, for example, an electron injection layer. The electron injection layer includes at least any of, for example, lithium fluoride, cesium fluoride, lithium quinoline complex, and the like. The third layer 33 can include a layer functioning as, for example, an electron transport layer. The electron transport layer includes at least any of, for example, Alq3 (tris(8-quinolinolate)aluminum (III)), BAlq (bis(2-methyl-8-quinolilate) (p-phenylphenolate)aluminum), Bphen (bathophenanthroline), 3TPYMB (tris[3-(3-pyridyl)-mesityl]borane), and the like. The third layer 33 may have a stacked structure, for example, of a layer functioning as an electron injection layer and a layer functioning as an electron transport layer. The third layer 33 may include a layer other than the layer functioning as an electron injection layer and a layer functioning as an electron transport layer. The third layer 33 is not limited to layers formed of these materials.

For example, the light emitted from the organic light emitting layer 30 is substantially white light. That is, the light emitted from the organic electroluminescent device 110 is white light. Here, “white light” is substantially white and also includes, for example, reddish, yellowish, greenish, bluish, and purplish white light.

The first electrode 10 contains an oxide containing at least one device selected from the group consisting of, for example, In, Sn, Zn and Ti. For example, a film of indium oxide, zinc oxide, tin oxide or indium tin oxide (ITO), a film manufactured using a conductive glass containing fluorine-doped tin oxide (FTO) or indium zinc oxide (such as NESA), gold, platinum, silver, copper or the like can be used for the first electrode 10. The first electrode 10 functions as, for example, an anode. Furthermore, as described above, a material substantially the same as that of the first electrode 10 is used for the first terminal part 51 and the second terminal part 52. The first electrode 10 is not limited to electrodes formed of these materials.

The second electrode 20 contains at least any of, for example, aluminum and silver. For example, an aluminum film is used for the second electrode 20. Furthermore, an alloy of silver and magnesium may be used for the second electrode 20. Calcium may be added to the alloy. The second electrode 20 functions as, for example, a cathode. The second electrode 20 is not limited to electrodes formed of these materials.

It is also possible to set the first electrode 10 as a cathode, to set the second electrode 20 as an anode, to cause the second layer 32 to function as an electron injection layer or an electron transport layer, and to cause the third layer 33 to function as a hole injection layer or a hole transport layer. Alternatively, it is also possible to form the first electrode 10 as a stacked structure of a light reflective electrode and a light transmissive electrode (such as a transparent electrode) and to pattern the same into a stripe-like shape or a grid-like shape as shown in FIGS. 2A and 2B, to thereby form the second electrode 20 as a light transmissive electrode (such as a transparent electrode). Consequently, a top emission type organic electroluminescent device 110 may be produced. It is also possible to set the first electrode 10 to be light reflective and to set the second electrode 20 to be light transmissive. In this case, when indicating a state having light reflectance higher than the light reflectance of the second electrode 20 as light reflective, the light reflectance of the second electrode 20 is higher than the light reflectance of the first electrode 10. In the case, additionally, the light reflectance of the first wiring layer 41 can be made higher than the light reflectance of the first electrode 10. Furthermore, the light reflectance of the second wiring layer 42 can be made higher than the light reflectance of the first electrode 10.

The first wiring layer 41 and the second wiring layer 42 contain at least any one device selected, for example, from the group consisting of Mo, Ta, Nb, Al, Ni and Ti. The first wiring layer 41 and the second wiring layer 42 may be a mixed film containing, for example, devices selected the group. The first wiring layer 41 and the second wiring layer 42 may be a stacked film containing these devices. For the first wiring layer 41 and the second wiring layer 42, for example, a stacked film of Nb/Mo/Al/Mo/Nb can be used. The first wiring layer 41 and the second wiring layer 42 function as, for example, an auxiliary electrode suppressing the potential fall of the first electrode 10. The first wiring layer 41 and the second wiring layer 42 can function as a lead electrode for feeding a current. The first wiring layer 41 and the second wiring layer 42 are not limited to electrodes formed of these materials.

For the insulating layer 45, for example, polyimide resin, acrylic resin, a silicon oxide film (for example SiO₂), a silicon nitride film (for example SiN), a silicon oxynitride film or the like is used. The insulating layer 45 is not limited to layers formed of these materials.

For the first substrate 81 and the second substrate 82, for example, a glass substrate, a resin substrate or the like is used. For example, ultraviolet-curable resin or the like is used for the seal part 85.

For example, a PET film, a PEN film or the like provided with ITO on one face or both faces thereof is used for the light transmissive coupling member 95. For example, the coupling member is connected to the first terminal part 51 and the second terminal part 52, by sticking the coupling member 95 by using an anisotropic conductive film (ACF), a light transmissive transparent conductive paste or the like. The coupling member 95 may also be, for example, a conductive sheet not having light permeability, or the like. For example, a wire or a lead wire of not less than 5 μm to not more than 2000 μm may be used for the coupling member 95. In the case, for example, the coupling member 95 is connected with the first terminal part 51 and the second terminal part 52 by wire bonding or soldering. In the case, by connecting a plurality of wires or lead wires and setting the pitch of the wires or lead wires to be not less than 10 μm to not more than 2000 μm, electric connection can be achieved while maintaining light permeability of the first terminal part 51 and the second terminal part 52.

The thickness of the first electrode 10 (the length in the Z-axis direction) is, for example, from not less than 10 nm to not more than 500 nm. In the example, the thickness of the first terminal part 51 and the thickness of the second terminal part 52 are, for example, not less than 10 nm and not more than 10 μm. The thickness of the organic light emitting layer 30 is, for example, not less than 10 nm and not more than 500 nm. The thickness of the second electrode 20 (the conductive part 20a) is, for example, from not less than 10 nm to not more than 500 nm. A width W1 of the conductive part 20a (the length in the X-axis direction) is, for example, from not less than 1 μm to not more than 2000 μm. A pitch Pt1 of the plurality of conductive parts 20a is, for example, not less than 2 μm to not more than 2000 μm. The pitch Pt1 is, for example, the distance in the X-axis direction between the centers of adjacent two conductive parts 20a in the X-axis direction.

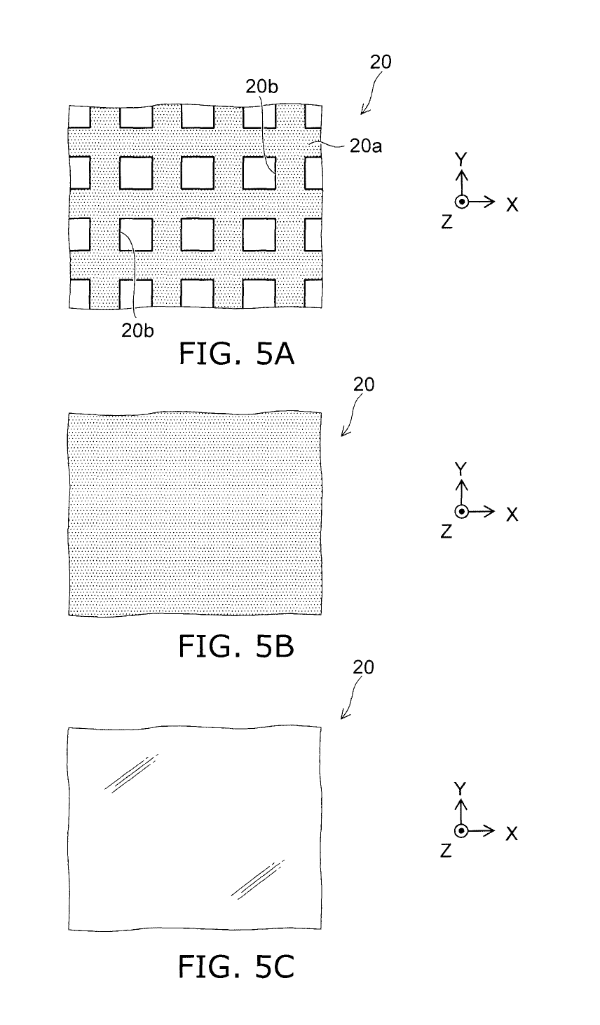

FIGS. 5A to 5C are schematic plan views showing a part of another organic electroluminescent device according to the first embodiment.

As shown in FIG. 5A, the second electrode 20 may be in a grid-like shape. In the example, the second electrode 20 includes one conductive part 20a and a plurality of aperture parts 20b. Each of the plurality of aperture parts 20b are arrayed in a two-dimensional matrix shape in the X-axis direction and the Y-axis direction. The shape of each of the plurality of aperture parts 20b projected onto the X-Y plane is, for example, rectangular. Consequently, the conductive part 20a gives a grid-like shape when being projected onto the X-Y plane. In the example, the pattern shape of the second electrode 20 is a grid-like shape. As described above, the pattern shape of the second electrode 20 is not limited to a stripe-like shape but may be a grid-like shape. In a grid-shaped second electrode 20, for example, the area of the emission region can be made large while making the width of the conductive part 20a thin, as compared with a stripe-shaped second electrode 20.

In the example, the shape of the aperture part 20b projected onto the X-Y plane is rectangular. The shape of the aperture part 20b is not limited to be rectangular, but, for example, may be a circular, elliptical or another polygonal shape. The shape of the aperture part 20b may be arbitrary. In the specification of the application, a “grid-like shape” includes a case where the aperture part has an arbitrary shape, in addition to the case where the aperture part has a rectangular shape. For example, a honeycomb-like shape shall also be included in the “grid-like shape.” That is, the pattern shape of the second electrode 20 may be a honeycomb-like shape, or the like.

As shown in FIG. 5B, the second electrode 20 may not include the aperture part 20b. That is, the second electrode 20 may overlap with the whole of the first electrode 10 when being projected onto a plane parallel to the X-Y plane. In the case, the organic electroluminescent device 110 does not have light permeability. In this way, the organic electroluminescent device 110 may not be light transmissive. In the case, the organic light emitting layer 30 and the second substrate 82 may not be light transmissive. In the case, the second substrate 82 may be a metal substrate, a light impermeable resin substrate, or the like.

As shown in FIG. 5C, the second electrode 20 may be light transmissive. The second electrode 20 may be, for example, transparent.

In the case, when being projected onto a plane parallel to the X-Y plane, the second electrode 20 may overlap with the whole of the first electrode 10.

In the case where a light transmissive second electrode 20 is used, when a voltage is applied to the organic light emitting layer 30 via the first electrode 10 and the second electrode 20, emission light emitted from the emission region exits to the outside of the organic electroluminescent device 110 via the first electrode 10 and exits to the outside of the organic electroluminescent device 110 via the second electrode 20. That is, an organic electroluminescent device 110 of a double-side light emission type can be achieved.

For the light transmissive second electrode 20, for example, materials described regarding the first electrode 10 can be used. Further, the light transmissive second electrode 20 may be, for example, a metal material such as MgAg obtained by adding Mg to Ag at a certain ratio. In the metal material, the thickness of the second electrode 20 is set to be not less than 5 nm and not more than 20 nm. Consequently, appropriate light permeability can be obtained. Alternatively, a stacked body of MgAg, Ag or Al of not less than 1 nm and not more than 20 nm and a transparent conductive film such as ITO may be used for a part of the second electrode 20.

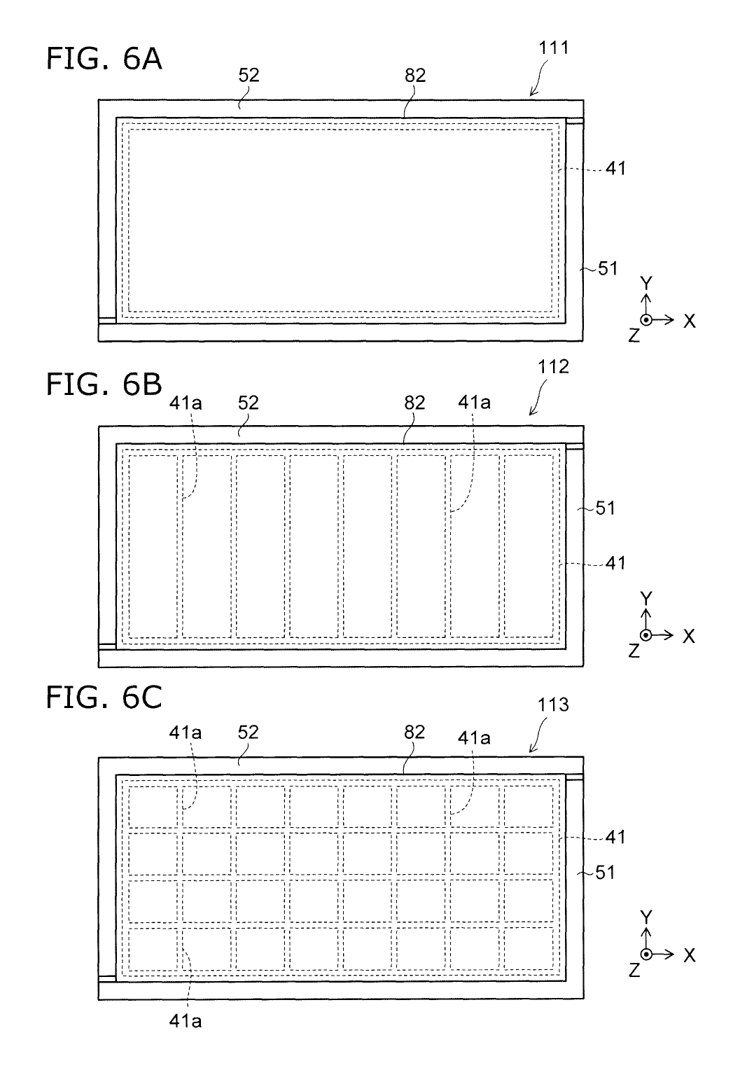

FIGS. 6A to 6C are schematic plan views showing other organic electroluminescent devices according to the first embodiment.

As shown in FIG. 6A, in an organic electroluminescent device 111, the first wiring layer 41 does not extends on the first terminal part 51. In this way, the first wiring layer 41 may be provided merely on the first electrode 10. In contrast to this, the first wiring layer 41 may be provided merely on the first terminal part 51. Furthermore, another wiring layer not connected physically to the first wiring layer 41 over the first electrode 10 may be provided on the first terminal part 51.

As shown in FIG. 6B, in an organic electroluminescent device 112, the first wiring layer 41 includes a plurality of aperture parts 41a. The plurality of aperture parts 41a extend in the Y-axis direction and are arranged side by side in the X-axis direction. In the example, the shape of the first wiring layer 41 projected onto the X-Y plane is a stripe-like shape. In this way, the first wiring layer 41 may be in a stripe-like shape.

As shown in FIG. 6C, in the organic electroluminescent device 113, the first wiring layer 41 includes a plurality of aperture parts 41a. The plurality of aperture parts 41a are arrayed in a two-dimensional matrix shape in the X-axis direction and the Y-axis direction. In the example, the shape of the first wiring layer 41 projected onto the X-Y plane is a grid-like shape. In this way, the first wiring layer 41 may be in a grid-like shape.

The shape of the first wiring layer 41 projected onto the X-Y plane may be an arbitrary shape. The first wiring layer 41 may have, for example, an arbitrary shape capable of flowing uniformly a current in the plane of the first electrode 10. It is sufficient that the first wiring layer 41 has, for example, a portion extending along the periphery of the first electrode 10.

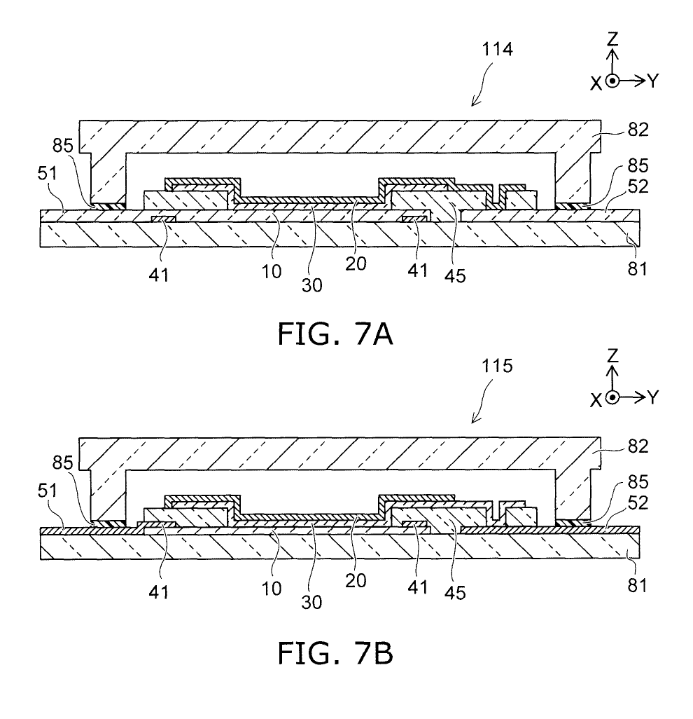

FIGS. 7A and 7B are schematic cross-sectional views showing other organic electroluminescent devices according to the first embodiment.

As shown in FIG. 7A, in the organic electroluminescent device 114, the first wiring layer 41 is disposed between the first substrate 81 and the first electrode 10. In this way, the first wiring layer 41 may be disposed between the first electrode 10 and the organic light emitting layer 30, or between the first substrate 81 and the first electrode 10. The first wiring layer 41 may be disposed both between the first electrode 10 and the organic light emitting layer 30 and between the first substrate 81 and the first electrode 10.

As shown in FIG. 7B, in the organic electroluminescent device 115, the first terminal part 51 includes substantially the same material as that of the first wiring layer 41. Further, the first terminal part 51 is continuous with the first wiring layer 41. The first terminal part 51 may have a stacked structure of the first electrode 10 and the first wiring layer 41 in a part. In the case, the first terminal part 51 is light reflective. In this way, the first terminal part 51 may be light reflective. When the first terminal part 51 is made light reflective, the first terminal part 51 may be formed integrally with the first wiring layer 41.

In the organic electroluminescent device 115, the second terminal part 52 is, for example, light reflective. The second terminal part 52 may be light reflective. When setting the second terminal part 52 to be light reflective, the second terminal part 52 may include a material substantially the same as that of the first wiring layer 41. That is, the second terminal part 52 may be formed from the same conductive film as that of the first wiring layer 41 and the first terminal part 51. Further, the second terminal part 52 may have a stacked structure of the first electrode 10 and the first wiring layer 41 in a part.

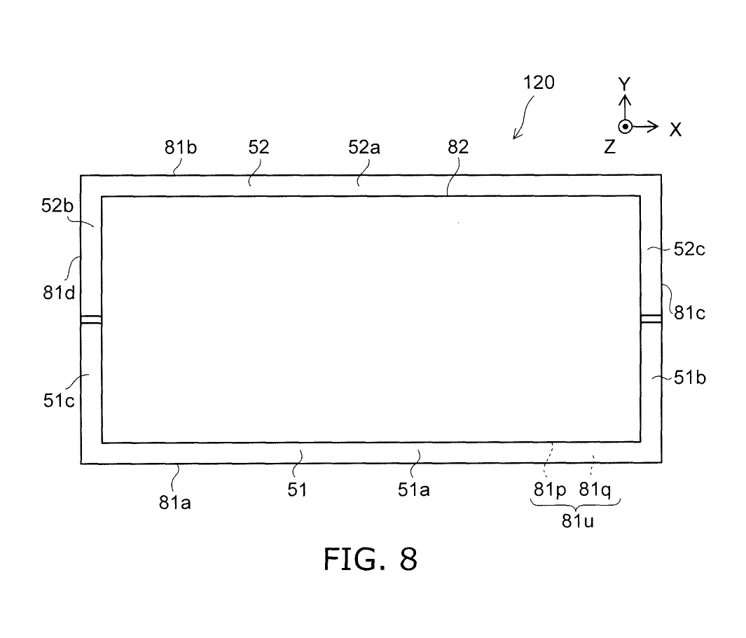

FIG. 8 is a schematic plan view showing another organic electroluminescent device according to the first embodiment.

As shown in FIG. 8, in an organic electroluminescent device 120, the first terminal part 51 further includes a portion 51c along the fourth side 81d of the upper face 81u, and the second terminal part 52 further includes a portion 52c along the third side 81c of the upper face 81u.

For example, the number of sides of the upper face 81u is assumed to be 2m. Here, “m” is an integer of not less than 2. That is, the number of sides of the upper face 81u is assumed to be an even number. In the case, in the organic electroluminescent device 120, the first terminal part 51 includes m+1 portions extending along each of continuous m+1 sides among the plurality of sides of the upper face 81u. Further, the second terminal part 52 includes m+1 portions extending along each of other continuous m+1 sides among the plurality of sides of the upper face 81u. At this time, the second terminal part 52 at least extends along each of remaining m−1 sides along which the first terminal part 51 does not extend among the plurality of sides of the upper face 81u.

On the other hand, for example, the number of the sides of the upper face 81u is assumed to be 2n+1. Here, “n” is an integer of not less than 1. That is, the number of sides of the upper face 81u is assumed to be an odd number. In the case, in the organic electroluminescent device 120, the first terminal part 51 includes n+1 portions extending along each of continuous n+1 sides among the plurality of sides of the upper face 81u. Further, the second terminal part 52 includes n+1 portions extending along each of other continuous n+1 sides among the plurality of sides of the upper face 81u. At this time, the second terminal part 52 at least extends along each of remaining n sides along which the first terminal part 51 does not extend among the plurality of sides of the upper face 81u.

In the organic electroluminescent device 120, the upper face 81u is quadrangular. That is, in the organic electroluminescent device 120, the case where m=2 is exemplified. Accordingly, in the example, the first terminal part 51 includes three portions 51a, 51b and 51c extending along each of continuous three sides of the upper face 81u. Furthermore, the second terminal part 52 includes three portions 52a, 52b and 52c extends along each of continuous three sides of the upper face 81u. One portion 52a of the second terminal part 52 extends along the second side 81b along which the first terminal part 51 does not extend.

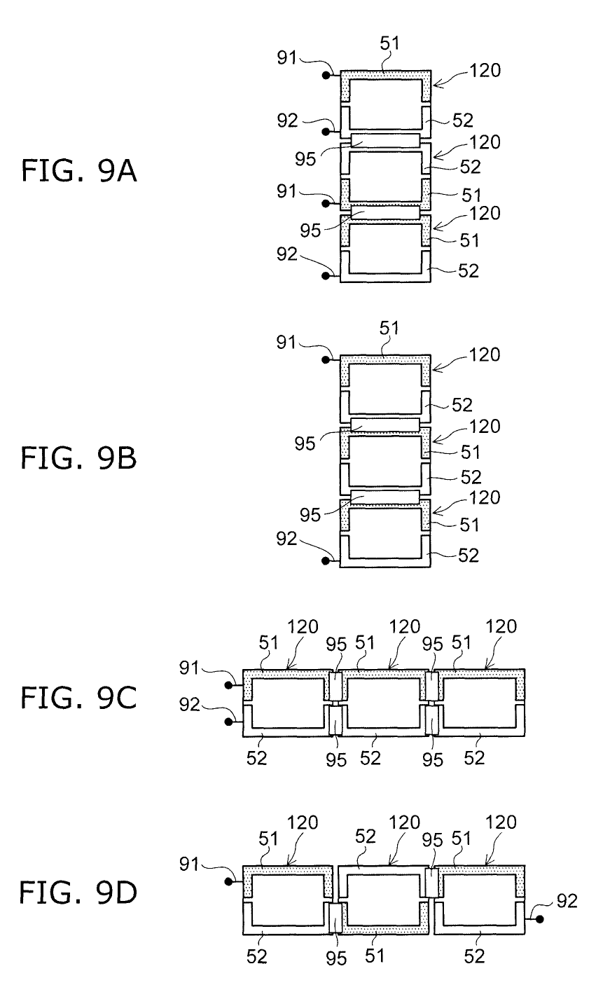

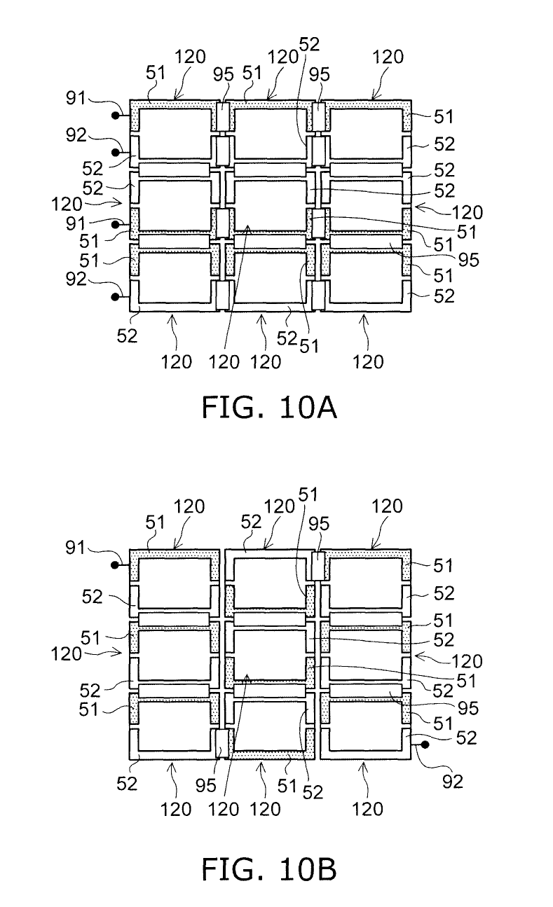

FIGS. 9A to 9D and FIGS. 10A and 10B are schematic plan views showing other organic electroluminescent devices according to the first embodiment.

FIG. 9A shows the state where three organic electroluminescent devices 120 are arranged side by side in the Y-axis direction and each thereof is connected in parallel.

FIG. 9B shows the state where three organic electroluminescent devices 120 are arranged side by side in the Y-axis direction and each thereof is connected in series.

FIG. 9C shows the state where three organic electroluminescent devices 120 are arranged side by side in the X-axis direction and each thereof is connected in parallel.

FIG. 9D shows the state where three organic electroluminescent devices 120 are arranged side by side in the X-axis direction and each thereof is connected in series.

FIG. 10A shows the state where nine organic electroluminescent devices 120 are arrayed in a two-dimensional matrix shape in the X-axis direction and the Y-axis direction and each thereof are connected in parallel.

FIG. 10B shows the state where nine organic electroluminescent devices 120 are arrayed in a two-dimensional matrix shape in the X-axis direction and the Y-axis direction and each thereof are connected in series.

As described above, in the organic electroluminescent device 120 according to the embodiment, for example, also in cases where the plurality of organic electroluminescent devices 120 arranged side by side in the X-axis direction are connected in parallel or the plurality of organic electroluminescent devices 120 arrayed in a two-dimensional matrix shape are connected in parallel, the width of the coupling member 95 can be made long. Each of the plurality of organic electroluminescent devices 120 can be easily wired in series or in parallel. Useless power consumption caused by the coupling member 95 can be suppressed. Further, since the connection area can be made large and the number of connection positons can be made large, the reliability on the connection can be improved.

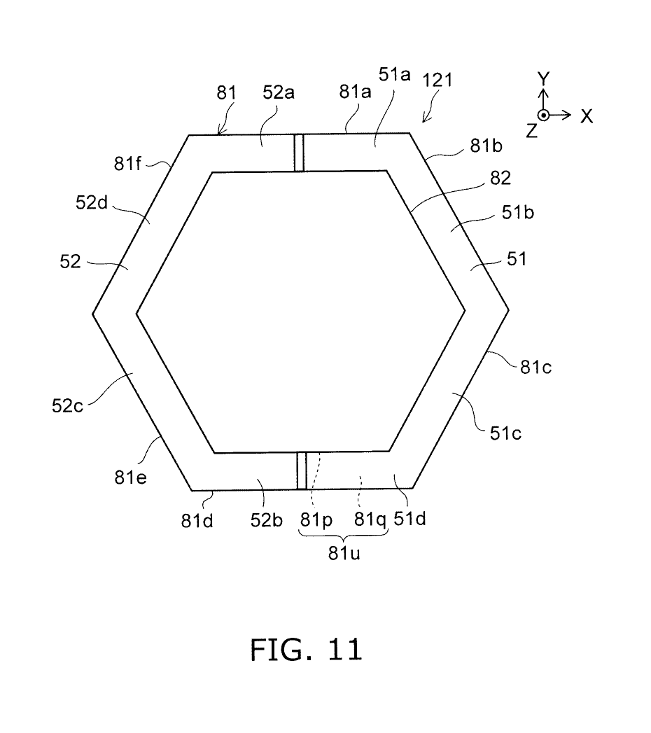

FIG. 11 is a schematic plan view showing another organic electroluminescent device according to the first embodiment.

As shown in FIG. 11, in an organic electroluminescent device 121, the upper face 81u of the first substrate 81 has a hexagonal shape having a first side 81a to a sixth side 81f. That is, the organic electroluminescent device 121 illustrates the case of m=3.

In the organic electroluminescent device 121, the first terminal part 51 includes four portions extending along each of continuous four sides of the upper face 81u. In the organic electroluminescent device 121, the first terminal part 51 includes a portion 51a along the first side 81a, a portion 51b along the second side 81b, a portion 51c along the third side 81c, and a portion 51d along the fourth side 81d.

In the organic electroluminescent device 121, the second terminal part 52 includes four portions extending along each of continuous four sides of the upper face 81u. In the organic electroluminescent device 121, the second terminal part 52 includes the portion 52a extending along the first side 81a, the portion 52b extending along the fourth side 81d, the portion 52c along the fifth side 81e, and the portion 52d extending along the sixth side 81f. The second terminal part 52 includes portions 52c and 52d extending along the fifth side 81e and sixth side 81f, respectively, along which the first terminal part 51 does not extend.

In this way, in the organic electroluminescent device 121, the first terminal part 51 including four portions 51a to 51d and the second terminal part 52 including four portions 52a to 52d are provided. Consequently, also in the case where the upper face 81u is made in a hexagonal shape, each of the plurality of organic electroluminescent devices 121 can be easily wired in series or in parallel.

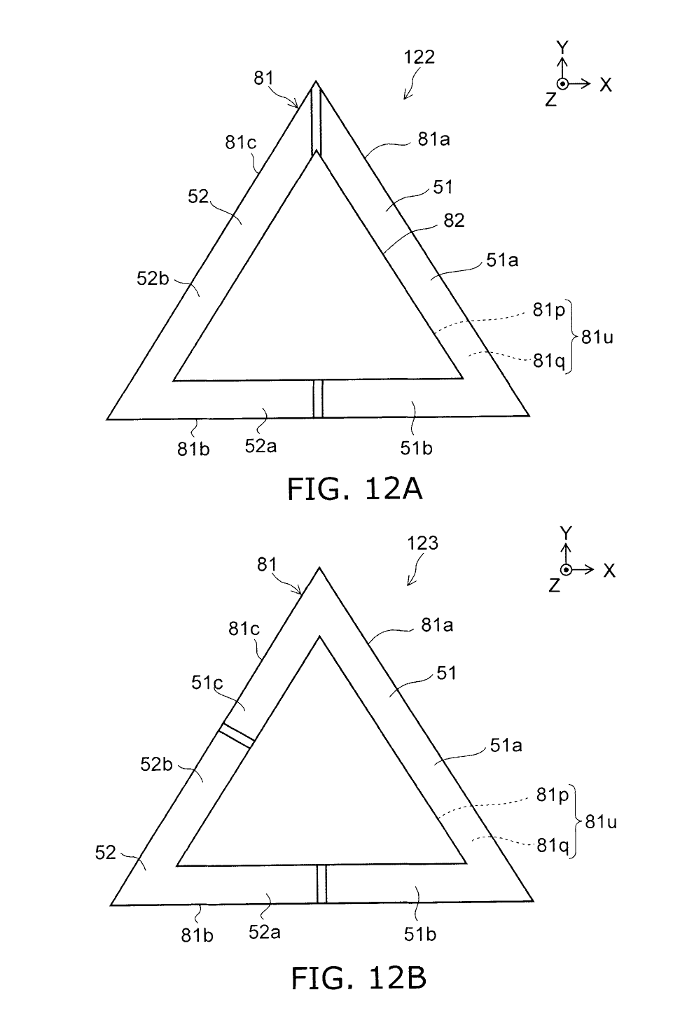

FIGS. 12A and 12B are schematic plan views of other organic electroluminescent devices according to the first embodiment.

As shone in FIG. 12A, in an organic electroluminescent device 122, the upper face 81u of the first substrate 81 is in a triangular shape having the first side 81a to the third side 81c. That is, the organic electroluminescent device 122 illustrates the case of n=1.

In the organic electroluminescent device 122, the first terminal part 51 includes two portions extending along each of continuous two sides of the upper face 81u. In the organic electroluminescent device 122, the first terminal part 51 includes the portion 51a extending along the first side 81a and the portion 51b extending along the second side 81b.

In the organic electroluminescent device 122, the second terminal part 52 includes two portions extending along each of continuous two sides of the upper face 81u. In the organic electroluminescent device 122, the second terminal part 52 includes the portion 52a extending along the second side 81b and the portion 52b extending along the third side 81c. The second terminal part 52 includes the portion 52b extending along the third side 81c along which the first terminal part 51 does not extend.

In this way, in the organic electroluminescent device 122, the first terminal part 51 including two portions 51a and 51b, and the second terminal part 52 including two portions 52a and 52b are provided. Consequently, also in the case where the upper face 81u is made triangular, each of the plurality of organic electroluminescent devices 122 can be easily wired in series or in parallel.

As shown in FIG. 12B, in an organic electroluminescent device 123, when the upper face 81u is made triangular, the first terminal part 51 further includes the portion 51c extending along the third side 81c. In the organic electroluminescent device 123, the first terminal part 51 extends along three sides of the upper face 81u and the second terminal part 52 extends along two sides of the upper face 81u. As described above, the number of sides along which the first terminal part 51 extends may be different from the number of sides along which the second terminal part 52 extends.

When the number of sides of the upper face 81u is 2m, it is sufficient that each of the first terminal part 51 and the second terminal part 52 extends along at least m+1 sides. When the number of the sides of the upper face 81u is 2n+1, it is sufficient that each of the first terminal part 51 and the second terminal part 52 extends along at least n+1 sides.

### Second Embodiment

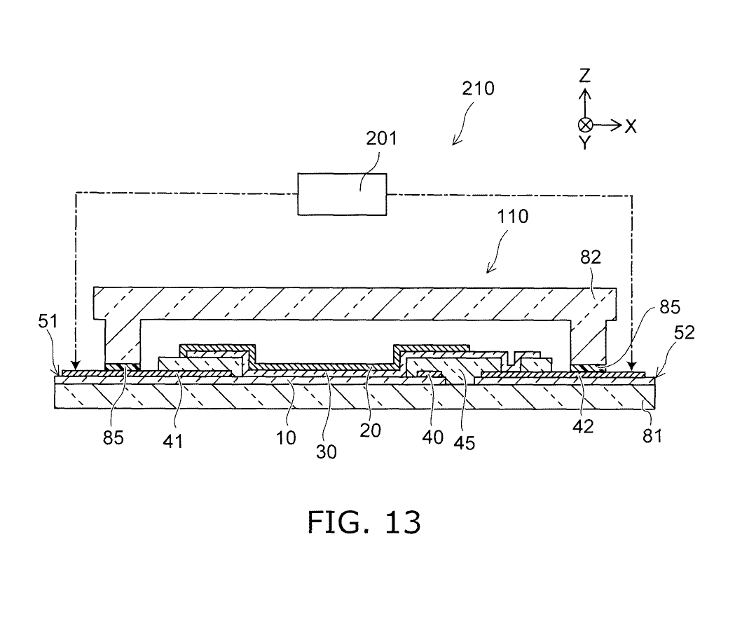

FIG. 13 is a schematic view showing an illumination apparatus according to a second embodiment.

As shown in FIG. 13, an illumination apparatus 210 according to the embodiment includes the organic electroluminescent device according to the first embodiment (for example, the organic electroluminescent device 110) and a power source 201.

The power source 201 is electrically connected to the first electrode 10 and the second electrode 20. The power source 201 supplies a current to the organic light emitting layer 30 via the first electrode 10 and the second electrode 20.

An illumination apparatus having high reliability can be provided by the illumination apparatus 210 according to the embodiment.

### Third Embodiment

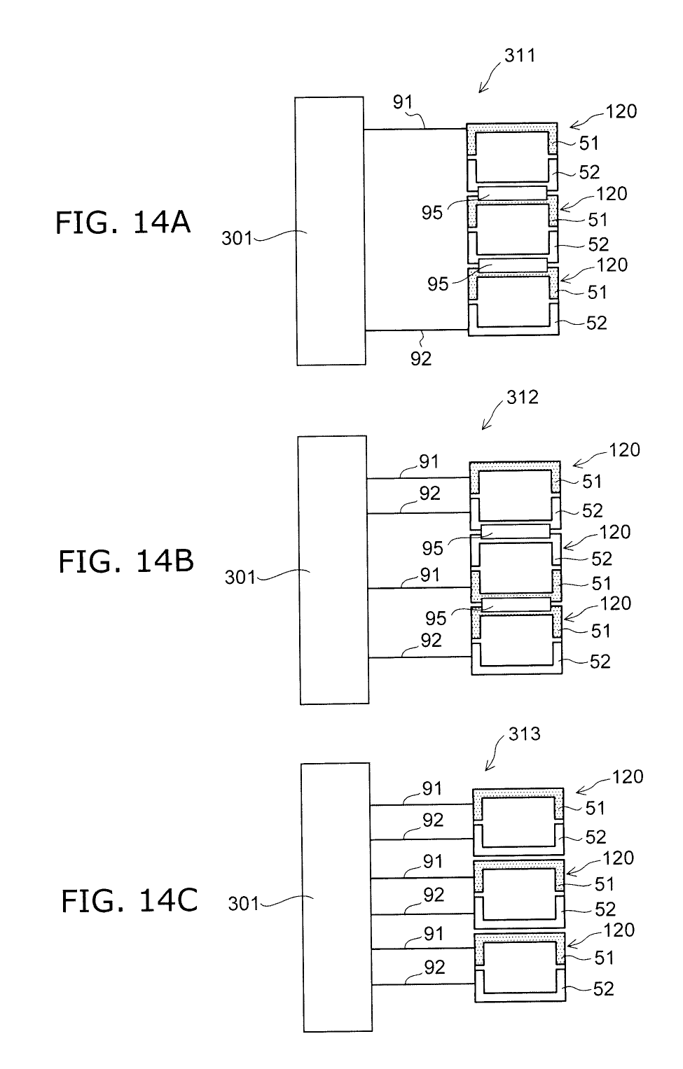

FIGS. 14A to 14C are schematic views showing illumination systems according to a third embodiment.

As shown in FIG. 14A, an illumination system 311 according to the embodiment includes a plurality of organic electroluminescent devices according to the first embodiment (for example, the organic electroluminescent device 120) and a controller 301.

The controller 301 is electrically connected to each of the plurality of organic electroluminescent devices 120, and controls turning on and off of each of the plurality of organic electroluminescent devices 120. In the illumination system 311, each of the plurality of organic electroluminescent devices 120 is connected in series. The controller 301 is electrically connected to the first terminal part 51 of one organic electroluminescent device 120 among the plurality of organic electroluminescent devices 120. Further, the controller 301 is electrically connected to the second terminal part 52 of another organic electroluminescent device 120 among the plurality of organic electroluminescent devices 120. Consequently, the controller 301 controls together turning on and off of each of the plurality of organic electroluminescent devices 120.

In the organic electroluminescent device 120, each of the plurality of organic electroluminescent devices 120 can be easily connected in series or in parallel by using the coupling member 95. For example, the electric connection between the plurality of organic electroluminescent devices 120 and the controller 301 can be easily performed. For example, in a light transmissive organic electroluminescent device 120, the first terminal part 51 and the second terminal part 52 are made light transmissive. Further, the coupling member 95 is made to be light transmissive. Consequently, the visibility of a transmission image can be enhanced.

As shown in FIG. 14B, in an illumination system 312, each of a plurality of organic electroluminescent devices 120 is connected in parallel. In the example, each of three organic electroluminescent devices 120 is connected in parallel. The controller 301 is electrically connected to the first terminal part 51 of a first organic electroluminescent device 120. The controller 301 is electrically connected to the second terminal part 52 of the first organic electroluminescent device 120. The controller 301 is electrically connected to the first terminal part 51 of a second organic electroluminescent device 120. Then, the controller 301 is electrically connected to a third second terminal part 52. Consequently, in the illumination system 312, turning on and off of respective organic electroluminescent devices 120 can be controlled individually by selecting one of four feeder wires.

As shown in FIG. 14C, in an illumination system 313, the controller 301 is electrically connected to the first electrode 10 and the second electrode 20 of each of a plurality of organic electroluminescent devices 120. Consequently, the controller 301 controls individually turning on and off of each of the plurality of organic electroluminescent devices 120. As described above, the controller 301 may control individually or may control together turning on and off of each of the plurality of organic electroluminescent devices 120.

In the organic electroluminescent device 120, for example, a plurality of devices can be easily wired. Consequently, for example, when causing a plurality of devices to be turned on/off individually, the number of feeder wires can be suppressed. For example, in the case where three organic electroluminescent devices are turned on/off individually, when wiring is to be performed with each of devices as is the case for the illumination system 313, six feeder wires become required. On the other hand, in the case of the organic electroluminescent device 120, as in the illumination system 312, individual turning on and off can be performed by four feeder wires by connecting respective devices in parallel. Furthermore, as in the illumination system 311, merely two feeder wires become required when respective devices are connected in series. As described above, in organic electroluminescent device 120 etc. according to the embodiment, the number of feeder wires required for the connection with the controller 301 can be suppressed.

By the illumination systems 311 to 313 according to the embodiment, illumination systems in which a plurality of devices can be easily wired each other can be provided.

By the embodiments, an organic electroluminescent device, an illumination apparatus and an illumination system that allow a plurality of devices to be wired easily each other are provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, embodiments of the invention are described with reference to specific examples. However, the embodiments of the invention are not limited to these specific examples. For example, one skilled in the art may similarly practice the invention by appropriately selecting specific configurations of components included in organic electroluminescent devices, illumination apparatuses, and illumination systems such as first electrodes, second electrodes, organic light emitting layers, wiring layers, first substrates, second substrates, first terminal parts, second terminal parts, power sources, controllers, etc., from known art; and such practice is included in the scope of the invention to the extent that similar effects are obtained.

Further, any two or more components of the specific examples may be combined within the extent of technical feasibility and are included in the scope of the invention to the extent that the purport of the invention is included.

Moreover, all organic electroluminescent devices, illumination apparatuses, and illumination systems practicable by an appropriate design modification by one skilled in the art based on the organic electroluminescent devices, illumination apparatuses, and illumination systems described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An organic electroluminescent device, comprising:
a first substrate having a upper face including a device region and a periphery region surrounding the device region, the upper face being polygonal, the first substrate being light transmissive;
a first electrode provided on the device region;
an organic light emitting layer provided on the first electrode;
a second electrode provided on the organic light emitting layer;
a second substrate provided on the second electrode and covering the organic light emitting layer and the second electrode;
a first terminal part provided on the periphery region and being electrically connected to the first electrode; and
a second terminal part provided separated from the first terminal part on the periphery region and being electrically connected to the second electrode,
the first terminal part including at least a portion extending along one side of the upper face and a portion extending along an adjacent side of the one side;
the second terminal part including at least a portion extending along other one side different from the one side and a portion extending along a side adjacent to the other one side; and
at least one of the first terminal part and the second terminal part extending along each of a plurality of sides of the upper face.

2. The device according to claim 1, wherein,
when number of sides of the upper face is 2m (m is an integer of not less than 2),
the first terminal part includes m+1 portions extending along each of continuous m+1 sides among a plurality of sides of the upper face; and
the second terminal part includes m+1 portions extending along each of other continuous m+1 sides among a plurality of sides of the upper face, and
when number of sides of the upper face is 2n+1 (n is an integer of not less than 1),
the first terminal part includes n+1 portions extending along each of continuous n+1 sides among a plurality of sides of the upper face; and
the second terminal part includes n+1 portions extending along each of continuous other n+1 sides among a plurality of sides of the upper face.

3. The device according to claim 2, wherein
the upper face is in a quadrangular shape including a first side, a second side facing the first side, a third side connecting one end of the first side with one end of the second side, and a fourth side connecting another end of the first side with another end of the second side;
the first terminal part includes a portion extending along the first side, a portion extending along the third side, and a portion extending along the fourth side; and
the second terminal part includes a portion extending along the second side, a portion extending along the third side, and a portion extending along the fourth side.

4. The device according to claim 1, wherein
each of the first terminal part and the second terminal part has light permeability.

5. The device according to claim 4, wherein
the first electrode has light permeability; and
the first terminal part includes a same material as that of the first electrode and is continuous with the first electrode.

6. The device according to claim 1, wherein
each of the organic light emitting layer and the second substrate has light permeability,
one of the first electrode and the second electrode has light reflectivity, and
the one of the first electrode and the second electrode does not overlap with a part of one other of the first electrode and the second electrode when projected onto a plane parallel to the upper face.

7. The device according to claim 6, wherein
the first electrode has light permeability; and
the second electrode has light reflectivity.

8. The device according to claim 7, wherein
the second electrode has a plurality of aperture parts; and
the aperture parts extend in a first direction parallel to the upper face and are arranged in a second direction, the second direction is parallel to the upper face and intersects with the first direction.

9. The device according to claim 7, wherein
the second electrode has a plurality of aperture parts;
the aperture parts are arranged in a first direction parallel to the upper face and are arranged in a second direction, the second direction is parallel to the upper face and intersects with the first direction.

10. The device according to claim 7, wherein
the second electrode overlaps with a whole of the first electrode when projected onto a plane parallel to the upper face.

11. The device according to claim 1, wherein
each of the organic light emitting layer, the first electrode, the second electrode, and the second substrate has light permeability.

12. The device according to claim 1, further comprising a first wiring layer electrically connected to at least one of the first electrode and the first terminal part and including a conductive material.

13. The device according to claim 12, wherein
the first wiring layer has light reflectivity and includes a plurality of aperture parts.

14. The device according to claim 12, wherein
the first terminal part and the first wiring layer have light reflectivity; and
the first terminal part includes a same material as that of the first wiring layer and is continuous with the first wiring layer.

15. The device according to claim 1, further comprising a second wiring layer electrically connected to the second terminal part.

16. The device according to claim 1, further comprising a seal part provided between the first substrate and the second substrate and sealing the first electrode, the second electrode, and the organic light emitting layer.

17. An illumination apparatus, comprising:
an organic electroluminescent device including:
a first substrate having a upper face including a device region and a periphery region surrounding the device region, the upper face being polygonal, the first substrate being light transmissive;
a first electrode provided on the device region;
an organic light emitting layer provided on the first electrode;
a second electrode provided on the organic light emitting layer;
a second substrate provided on the second electrode and covering the organic light emitting layer and the second electrode;
a first terminal part provided on the periphery region and being electrically connected to the first electrode; and
a second terminal part provided separated from the first terminal part on the periphery region and being electrically connected to the second electrode; and
a power source electrically connected to the first electrode and the second electrode and supplying a current to the organic light emitting layer via the first electrode and the second electrode,
the first terminal part including at least a portion extending along one side of the upper face and a portion extending along an adjacent side of the one side;
the second terminal part including at least a portion extending along other one side different from the one side and a portion extending along a side adjacent to the other one side; and
at least one of the first terminal part and the second terminal part extending along each of a plurality of sides of the upper face.

18. An illumination system, comprising:
a plurality of organic electroluminescent devices, each of the organic electroluminescent devices including:
a first substrate having a upper face including a device region and a periphery region surrounding the device region, the upper face being polygonal, the first substrate being light transmissive;
a first electrode provided on the device region;
an organic light emitting layer provided on the first electrode;
a second electrode provided on the organic light emitting layer;
a second substrate provided on the second electrode and covering the organic light emitting layer and the second electrode;
a first terminal part provided on the periphery region and being electrically connected to the first electrode; and
a second terminal part provided separated from the first terminal part on the periphery region and being electrically connected to the second electrode; and
a controller electrically connected to each of the organic electroluminescent devices and controlling turning on and off of each of the organic electroluminescent devices,
the first terminal part including at least a portion extending along one side of the upper face and a portion extending along an adjacent side of the one side;
the second terminal part including at least a portion extending along other one side different from the one side and a portion extending along a side adjacent to the other one side; and
at least one of the first terminal part and the second terminal part extending along each of a plurality of sides of the upper face.

19. The system according to claim 18, further comprising a coupling member,
each of the organic electroluminescent devices being disposed side by side,
the coupling member being light transmissive, and
the coupling member electrically connecting the first terminal part of one of the organic electroluminescent device among the plurality of organic electroluminescent devices with one of the first terminal part and the second terminal part of other one of the organic electroluminescent device adjacent to the one organic electroluminescent device.

20. The system according to claim 19, wherein
the coupling member is a conductive member to which a lead wire is soldered and a bonded conductive wire.
